(19) United States
(12) Patent Application Publication
(10) Pub. No.: US 2007/0215917 A1
(43) Pub. Date: Sep. 20, 2007

(54) Semiconductor integrated circuit device and a method of manufacturing the same

(75) Inventor: Yasuhiro Taniguchi, Tokyo (JP)

Correspondence Address: MILES & STOCKBRIDGE PC, 1751 PINNACLE DRIVE, SUITE 500, MCLEAN, VA, 22102-3833, US

(73) Assignee: Renesas Technology Corp.

(21) Appl. No.: 11/698,877

(22) Filed: Jan. 29, 2007

(30) Foreign Application Priority Data
Mar. 20, 2006 (JP) 2006-76848

(51) Int. Cl. H01L 29/76

(52) U.S. Cl. 257/288

(57) ABSTRACT

Provided is a technology capable of manufacturing, in a short TAT, a mask ROM having a small memory cell area and high reliability. According to the manufacturing method of a semiconductor integrated circuit device according to the present invention, a memory cell is formed of a first MISFET equipped with an n type gate electrode composed of a polycrystalline silicon film having an n conductivity type impurity introduced therein and a second MISFET equipped with a p type gate electrode composed of a polycrystalline silicon film having a p conductivity type impurity introduced therein. In the n type gate electrode and p type gate electrode, an n conductivity type impurity is introduced further, whereby a threshold voltage of the first MISFET is made lower than that of the second MISFET.

### CROSS-REFERENCE TO RELATED APPLICATION

The present application claims priority from Japanese patent application No. 2006-76848 filed on Mar. 20, 2006, the content of which is hereby incorporated by reference into this application.

### BACKGROUND OF THE INVENTION

The present invention relates to a semiconductor integrated circuit device and a manufacturing technology thereof, in particular, to a semiconductor integrated circuit device having a mask ROM (Read Only Memory) and a technology effective when applied to the manufacture thereof.

In Japanese Unexamined Patent Publication No. Hei 8(1996)-125036, there are disclosed a mask ROM making use, for bit information, of a difference in work function brought about by difference in the impurity concentration or polarity of the impurity in a gate electrode, and a manufacturing method of the mask ROM.

### DISCLOSURE OF THE INVENTION

A mask ROM is a ROM which uses an MOS transistor as a memory cell and has a circuit on which data have been written as a pattern during its manufacture. Data are recorded during its manufacture so that they cannot be re-written later. In other words, it has a structure enabling size reduction of a memory cell, high integration and manufacture at a low cost because it does not need a circuit for writing. A mask ROM has therefore been used widely in applications where a large demand can be expected in advance such as program cassettes for home video game consoles and household appliances to be mass produced.

Data are written in mask ROM by:

(a) selectively implanting threshold-voltage regulating ions in advance into an active region (well) on which an MOS transistor to be a memory cell is formed, thereby controlling a channel current of the MOS transistor;

(b) selectively implanting, after formation of the gate electrode and source.drain of an MOS transistor which will be memory cell, threshold-voltage regulating ions in an active region (well) below the gate electrode of the MOS transistor, thereby controlling a channel current of the MOS transistor;

(c) controlling conduction, depending on whether contact holes are formed or not on semiconductor regions which are source and drain of an MOS transistor which will be a memory cell, or the like.

The method (a) is advantageous because it can reduce fluctuations in the threshold voltage and decrease the area of the memory cell. On the other hand, a change in a ROM pattern (write data) requires a change in a mask for implanting ions into an active region (well), which needs a further change in the initial manufacturing step of a mask ROM. Thus, it has an influence on subsequent steps and inevitably extends TAT (Turn Around Time) for the manufacture of the mask ROM. In addition, necessity of a mask exclusively used for implanting threshold-voltage regulating ions into an active region (well) causes an increase in the production cost.

Use of the method (b) can shorten TAT for the manufacture of a mask ROM when the ROM pattern must be changed, compared with the use of the method (a). However, ion implantation for regulating a threshold voltage is carried out via a gate electrode so that fluctuations in a threshold voltage inevitably increase. In addition, similar to the method (a), necessity of a mask exclusively used for implanting threshold-voltage regulating ions into an active region (well) inevitably raises a production cost.

When the method (a) or (b) is employed, the area of a memory cell can be reduced by using a source interconnect in common among MOS transistors constituting plural bits of data. Use of the method (c), on the other hand, inevitably increases the area of a memory cell because one bit of data needs both a source interconnect and a drain interconnect.

An object of the present invention is to provide a technology capable of manufacturing a mask ROM featuring a short TAT and a small memory cell area.

Another object of the invention is to provide a technology of manufacturing a mask ROM having a high reliability.

The above-described and other objects and novel features of the present invention will be apparent from the description herein and accompanying drawings.

Outline of the typical inventions, of those disclosed by the present application, will next be described briefly.

(1) A semiconductor integrated circuit device according to the present invention comprises:

a plurality of first channel type first MISFETs having a first gate electrode of a first conductivity type; and

a plurality of first channel type second MISFETs having a second gate electrode of a second conductivity type, wherein:

the first MISFETs and the second MISFETs constitute a memory cell of a mask ROM.

(2) A semiconductor integrated circuit device comprises:

a plurality of first channel type first MISFETs having a first gate electrode equipped with a first work function and made of a first metal film, a first metal compound film or a first film stack thereof; and

a plurality of first channel type second MISFETs having a first gate electrode equipped with a second work function and made of a second metal film, a second metal compound film or a second film stack thereof, wherein:

the first MISFETs and the second MISFETs constitute a memory cell of a mask ROM, and

data is stored in the memory cell according to a difference in work function between the first gate electrode and the second gate electrode.

(3) A manufacturing method of a semiconductor integrated circuit device according to the present invention having a memory portion and a peripheral circuit portion in a first region and a second region of a semiconductor substrate, respectively, comprises:

(a) forming a first conductive film having a first conductivity type and a second conductive film having a second conductivity type in each of the first region and the second region;

(b) patterning the first conductive film and the second conductive film to form a first gate electrode of the first conductivity type and a second gate electrode of the second conductivity type in the first region and a third gate electrode of the first conductivity type and a fourth gate electrode of the second conductivity type in the second region;

(c) selectively implanting a first impurity of the first conductivity type into the surface of the semiconductor substrate including the surfaces of the first gate electrode, second gate electrode and third gate electrode to form first semiconductor regions of the first conductivity type, thereby forming, in the first region, a plurality of first channel type first MISFETs equipped with the first gate electrode and having the first semiconductor regions as source and drain and a plurality of first channel type second MISFETs equipped with the second gate electrode and having the first semiconductor regions as source and drain, while forming, in the second region, a plurality of first channel type third MISFETs equipped with the third gate electrode and having the first semiconductor regions as source and drain; and

(d) selectively implanting a fourth impurity of the second conductivity type into the surface of the semiconductor substrate including the surface of the fourth gate electrode to form second semiconductor regions of the second conductivity type, thereby forming, in the second region, a plurality of second-channel type fourth MISFETs equipped with the fourth gate electrode and having the second semiconductor regions as source and drain.

(4) A manufacturing method of a semiconductor integrated circuit device according to the present invention having a memory portion and a peripheral circuit portion in a first region and a second region of a semiconductor substrate, respectively, comprises:

(a) forming a first metal film, a first metal compound film or a first film stack thereof equipped with a first work function over the semiconductor substrate and patterning to selectively leave the first metal film, the first metal compound film or the first film stack thereof to form a first gate electrode in the first region and a third gate electrode in the second region;

(b) forming a second metal film, a second metal compound film or a second film stack equipped with a second work function over the semiconductor substrate and then patterning to selectively leave the second metal film, the second metal compound film or the second film stack thereof to form a second gate electrode in the first region and a fourth gate electrode in the second region;

(c) selectively implanting a first impurity of the first conductivity type into the surface of the semiconductor substrate to form first semiconductor regions of the first conductivity type, thereby forming, in the first region, a plurality of first channel type first MISFETs equipped with the first gate electrode and having the first semiconductor regions as source and drain and a plurality of first channel type second MISFETs equipped with the second gate electrode and having the first semiconductor regions as source and drain, while forming, in the second region, a plurality of first channel type third MISFETs equipped with the third gate electrode and having the first semiconductor regions as source and drain; and

(d) selectively implanting a fourth impurity of the second conductivity type into the surface of the semiconductor substrate to form second semiconductor regions of the second conductivity type, thereby forming, in the second region, a plurality of second channel type fourth MISFETs equipped with the fourth gate electrode and having the second semiconductor regions as source and drain.

The advantage available by the typical invention, of those disclosed by the present application, will next be described.

According to the present invention, a mask ROM having a small memory cell area and high reliability can be manufactured within a short TAT.

### BRIEF DESCRIPTION OF THE DRAWINGS

FIG. 1 is a fragmentary circuit diagram illustrating a portion of the circuit structure of a mask ROM which a semiconductor integrated circuit device according to Embodiment 1 of the present invention has;

FIG. 2 is a schematic view illustrating a data map corresponding to the circuit structure of the mask ROM illustrated in FIG. 1;

FIG. 3 is a fragmentary plan view showing a manufacturing method of the semiconductor integrated circuit device according to Embodiment 1 of the present invention;

FIG. 4 is a fragmentary cross-sectional view illustrating the manufacturing method of the semiconductor integrated circuit device according to Embodiment 1 of the present invention;

FIG. 5 is a fragmentary plan view of the semiconductor integrated circuit device according to Embodiment 1 of the present invention during a manufacturing step thereof;

FIG. 6 is a fragmentary plan view of the semiconductor integrated circuit device according to Embodiment 1 of the present invention during a manufacturing step thereof;

FIG. 7 is a fragmentary cross-sectional view of the semiconductor device during a manufacturing step following that of FIG. 4;

FIG. 8 is a fragmentary plan view of the semiconductor integrated circuit device according to Embodiment 1 of the present invention during a manufacturing step thereof;

FIG. 9 is a fragmentary cross-sectional view of the semiconductor integrated circuit device during a manufacturing step following that of FIG. 7;

FIG. 10 is a fragmentary cross-sectional view of the semiconductor integrated circuit device during a manufacturing step following that of FIG. 9;

FIG. 11 is a fragmentary cross-sectional view of the semiconductor integrated circuit device during a manufacturing step following that of FIG. 10;

FIG. 12 is a fragmentary cross-sectional view of the semiconductor integrated circuit device during a manufacturing step following that of FIG. 11;

FIG. 13 is a fragmentary plan view of the semiconductor integrated circuit device according to Embodiment 1 of the present invention during a manufacturing step thereof;

FIG. 14 is a fragmentary cross-sectional view of the semiconductor integrated circuit device during a manufacturing step following that of FIG. 12;

FIG. 15 is a fragmentary cross-sectional view of the semiconductor integrated circuit device during a manufacturing step following that of FIG. 14;

FIG. 16 is a fragmentary cross-sectional view of the semiconductor integrated circuit device during a manufacturing step following that of FIG. 15;

FIG. 17 is a fragmentary cross-sectional view of the semiconductor integrated circuit device during a manufacturing step following that of FIG. 16;

FIG. 18 is a fragmentary cross-sectional view of a semiconductor integrated circuit device according to Embodiment 2 of the present invention during a manufacturing step thereof;

FIG. 19 is a fragmentary cross-sectional view of the semiconductor integrated circuit device during a manufacturing step following that of FIG. 18; and

FIG. 20 is a fragmentary cross-sectional view of a semiconductor integrated circuit device according to Embodiment 3 of the present invention during a manufacturing step thereof.

### DETAILED DESCRIPTION OF THE INVENTION

In the below-described embodiments, a description will be made after divided into plural sections or into plural embodiments if necessary for convenience's sake. These plural sections or embodiments are not independent from each other, but in a relation such that one is a modification example, details or complementary description of a part or whole of the other one unless otherwise specifically indicated.

In the below-described embodiments, when a reference will be made to the number of elements (including the number, value, amount and range), the number of elements is not limited to a specific number but may be greater than or less than the specific number unless otherwise specifically indicated or apparently limited to a specific number in principle.

Moreover in the below-described embodiments, it is needless to say that the constituting elements (including element steps) are not always essential unless otherwise specifically indicated or unless otherwise presumed to be apparently indispensable in principle. In addition, it is needless to say that in the embodiments and the like, the description relating to the constituting elements such as “composed of A” or “made of A” does not eliminate other elements unless otherwise specifically indicated that only A is a constituting element.

Similarly, in the below-described embodiments, when a reference will be made to the shape or positional relationship of the constituting elements, that substantially analogous or similar to it is also embraced unless otherwise specifically indicated or unless otherwise presumed to be apparently different in principle. This also applies to the above-described value and range.

When a reference will be made to a material or the like, the material specified is a main material and use of a subsidiary factor, additive, additive element or the like is not excluded unless otherwise specifically indicated or unless apparently inappropriate judging from situations. For example, the term “silicon member” means not only pure silicon but also a binary or tertiary alloy (such as SiGe) having an additive impurity and silicon as main components, unless otherwise specifically indicated.

In all the drawings for illustrating the embodiments of the present invention, members having the same function will be identified by the same reference numerals, and overlapping descriptions will be omitted.

In the drawings which will be used in the embodiments of the present invention, even a plan view is sometimes hatched partially in order to facilitate its understanding.

The embodiments of the present invention will hereinafter be described more specifically based on accompanying drawings.

### Embodiment 1

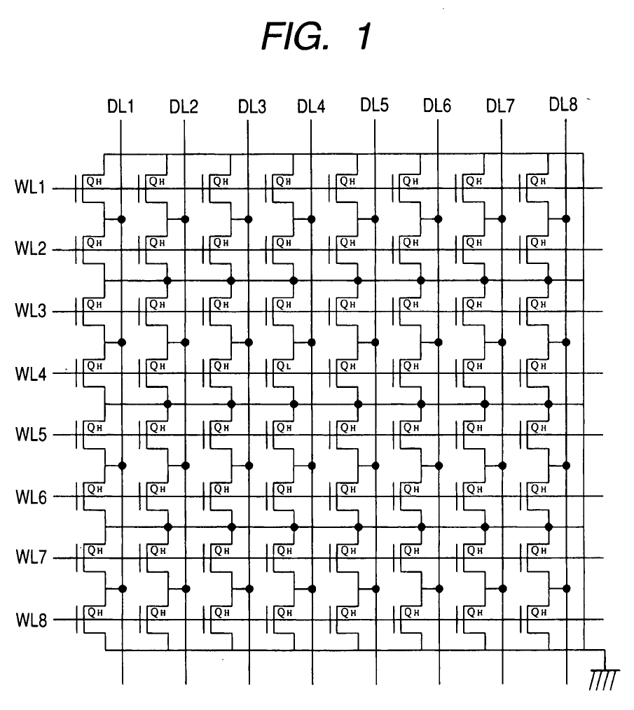

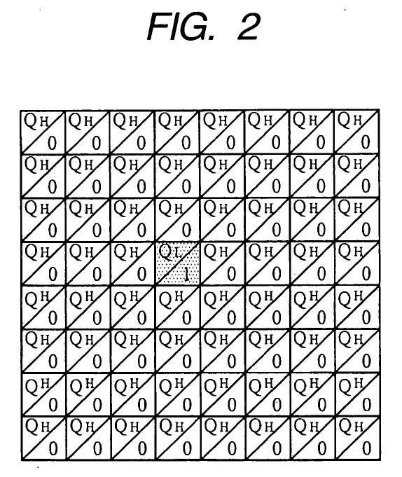

A semiconductor integrated circuit device according to Embodiment 1 has a mask ROM. FIG. 1 is a fragmentary circuit diagram illustrating a portion of the circuit structure of this mask ROM, while FIG. 2 is a schematic view illustrating the data map corresponding to the circuit structure of FIG. 1.

As illustrated in FIGS. 1 and 2, the memory cell of the mask ROM of Embodiment 1 is composed of an MISFET (Metal Insulator Semiconductor Field Effect Transistor) QH having a relatively high threshold voltage and an MISFET QL having a relatively low threshold voltage. In the MISFETs QH and QL, gates are each electrically connected to one of word lines WL1 to WL8, drains are each electrically connected to one of data lines DL1 to DL8, and sources are electrically connected to each other by a common interconnect and electrically connected to a reference potential (ground potential). The memory cell is thus formed of MISFETs QH and QL different in threshold voltage so that when an arbitrary MISFET QH is selected, “0” is read out because no current flows through the MISFET QH (the MISFET QH is not turned ON) and when an arbitrary MISFET QL is selected, “1” is read out because a current flows through the MISFET QL (the MISFET QL is turned ON).

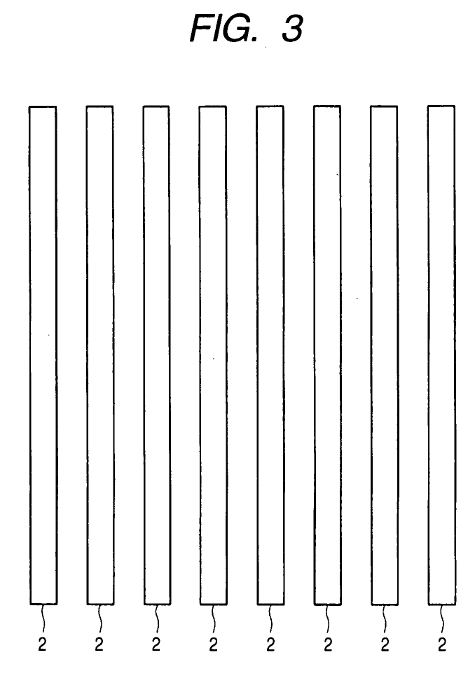

Manufacturing steps of the semiconductor integrated circuit device having a mask ROM according to Embodiment 1 will next be described referring to FIGS. 3 to 17. Of FIGS. 3 to 17, FIGS. 3, 5, 6, 8 and 13 are plan views illustrating a portion of a region (first region) in which a memory cell of the mask ROM is to be formed, while the others are fragmentary cross-sectional views illustrating a region (memory cell region) in which the memory cell is to be formed and fragmentary cross-sectional views illustrating a region (second region) in which a peripheral circuit (peripheral circuit region) is to be formed. The peripheral circuit includes a row decoder circuit, a column decoder circuit and an input/output control circuit.

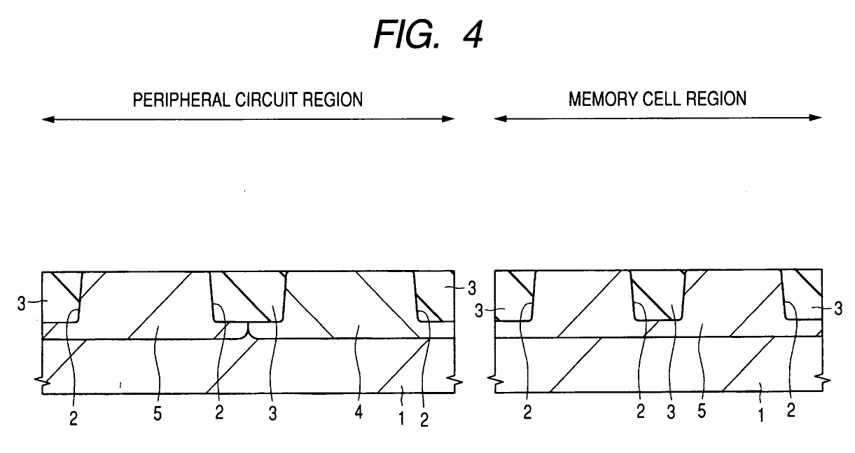

As illustrated in FIGS. 3 and 4, element isolation portions 2 are formed on the main surface (element formation surface) of a semiconductor substrate (which will hereinafter be called “substrate”, simply) 1. These element isolation portions 2 can each be formed in the following manner. First, a trench is formed by etching the main surface of the substrate 1 made of p type single crystal silicon having a specific resistance of from about 1 to 10 Ocm. The substrate 1 is then thermally oxidized at about 1000° C. to form a thin silicon oxide film (not illustrated) on the inner wall of the trench. This silicon oxide film is formed in order to repair the damage caused on the inner wall of the trench by dry etching and at the same time to relax the stress which will occur on the interface between the substrate 1 and a silicon oxide film to be filled inside the trench in the subsequent step. A silicon oxide film 3 is then deposited, as an insulating film, on the substrate 1 including the inside of the trench, for example, by CVD (Chemical Vapor Deposition). The silicon oxide film 3 on the trench is then polished by CMP (Chemical Mechanical Polishing) to leave the silicon oxide film 3 inside the trench, whereby the element isolation portion 2 is formed.

After selective ion implantation of an impurity (for example, P (phosphorus)) having an n (first conductivity) conductivity type and an impurity (for example, B (boron)) having a p (second conductivity) conductivity type into the substrate 1, the substrate 1 is heat treated to diffuse these impurities, whereby an n well 4 and p well 5 are formed on the substrate 1. At this time, an active region which is a main surface of the n well 4 and p well 5 is formed over the substrate 1.

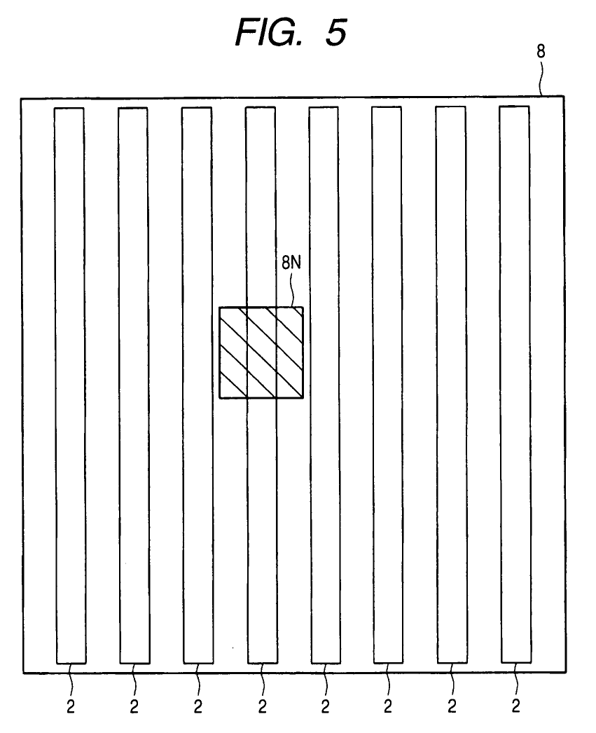

As illustrated in FIGS. 5 to 7, the surface of the substrate 1 (n well 4 and p well 5) is then wet cleaned, for example, with a hydrofluoric acid cleaning solution, followed by the heat treatment of the substrate 1, whereby a clean gate insulating film 7 is formed on the surface of each of the n well 4 and p well 5.

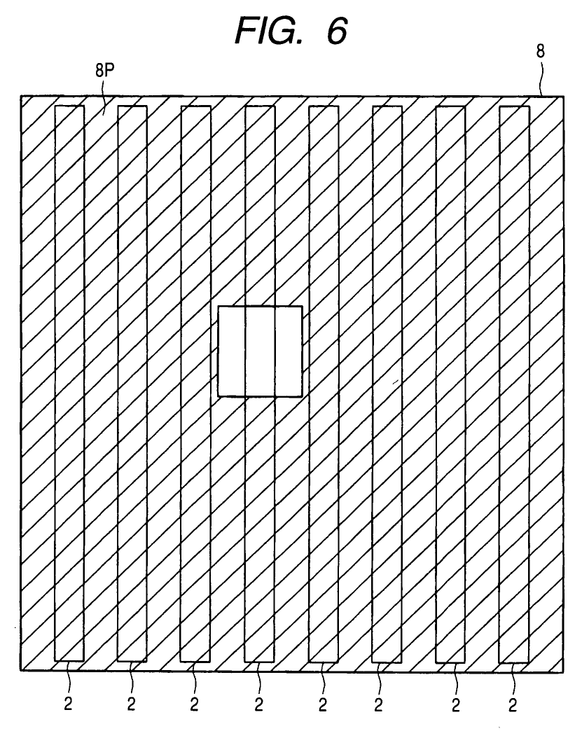

A low-resistance polycrystalline silicon film 8 having a thickness of about 100 nm is then deposited as a conductive film on the substrate 1, for example, by CVD. With a photoresist film patterned by photolithography as a mask, an n conductivity type impurity (for example, P or As (arsenic)) is introduced selectively into the polycrystalline silicon film 8 to form an n type polycrystalline silicon film (first conductive film) 8N. In FIG. 5, a hatched region is a region in which an n conductivity type impurity has been introduced (a region in which an n type polycrystalline silicon film 8N has been formed). With a photoresist film patterned newly by photolithography as a mask, a p conductivity type impurity (for example, B) is introduced selectively into the polycrystalline silicon film 8 to form a p type polycrystalline silicon film (second conductive film) 8P. In FIG. 6, a hatched region is a region in which a p conductivity type impurity has been introduced (a region in which a p type polycrystalline silicon film 8P has been formed). These steps for forming the n type polycrystalline silicon film 8N and for forming the p type polycrystalline film 8P may be carried out in any order.

A silicon oxide film 9 is then deposited on the n type polycrystalline silicon film 8N and p type polycrystalline silicon film 8P.

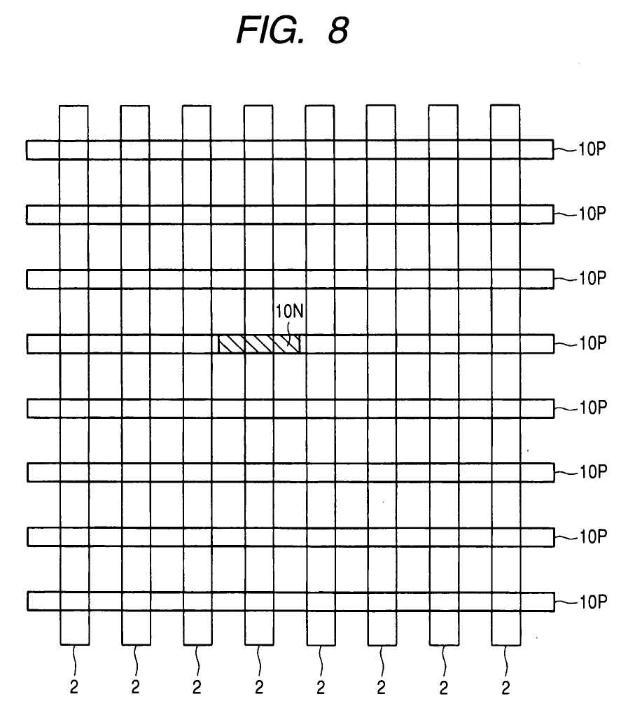

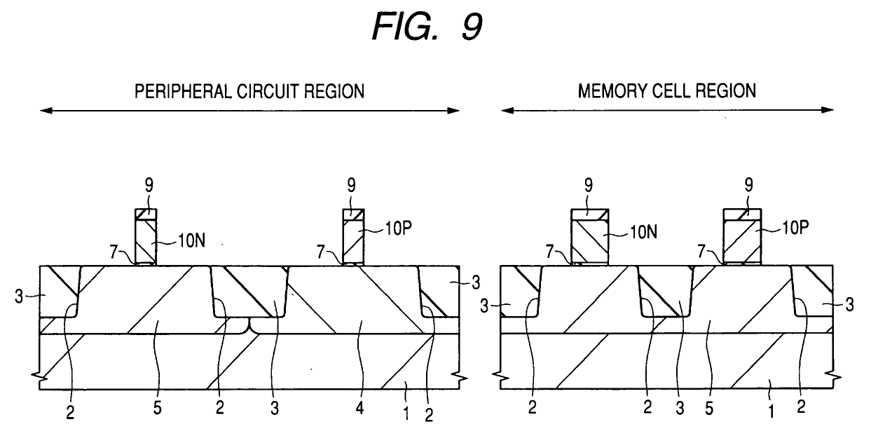

As illustrated in FIGS. 8 and 9, with a photoresist film patterned by photolithography as a mask, the n type polycrystalline silicon film 8N and p type polycrystalline silicon film 8P are etched to form n type gate electrodes (first gate electrode and third gate electrode) 10N made of the n type polycrystalline silicon film 8N and p type gate electrodes (second gate electrode and fourth gate electrode) 10P made of the p type polycrystalline silicon film 8P. In FIG. 8, the n type gate electrode 10N is illustrated as a hatched region.

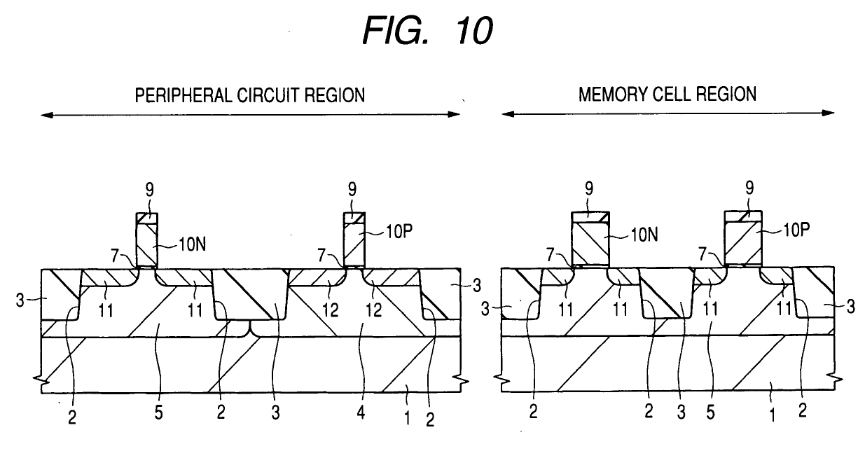

As illustrated in FIG. 10, an n conductivity type impurity (for example, As or P) is introduced into the p well 5 on both sides of the n type gate electrode 10N and p type gate electrode 10P in the memory cell region and peripheral circuit region, whereby lightly-doped n⁻ type semiconductor regions 11 are formed. Then, a p conductivity type impurity (for example, B) is introduced into the n well 4 on both sides of the p type gate electrode 10P in the peripheral circuit region, whereby lightly-doped p⁻ type semiconductor regions 12 are formed. The n⁻ type semiconductor regions 11 and p⁻ type semiconductor regions 12 may be formed in any order. An LDD (Lightly Doped Drain) structure can be formed by forming these n⁻ type semiconductor regions 11 and p⁻ type semiconductor regions 12.

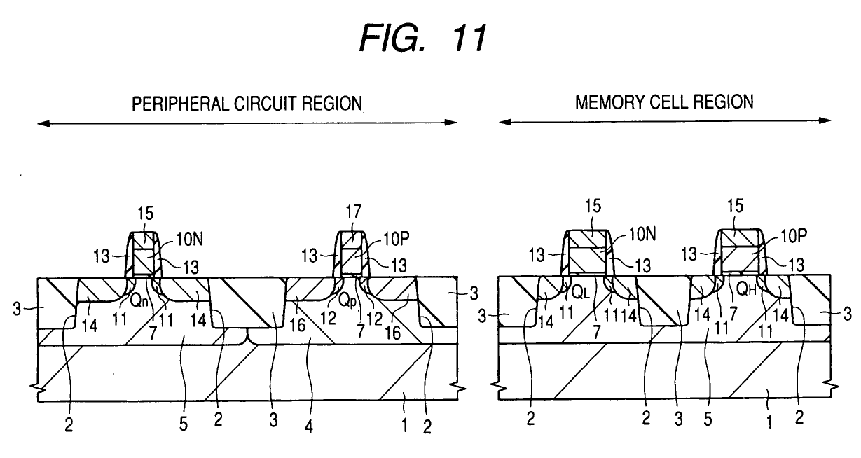

As illustrated in FIG. 11, after deposition of a silicon oxide film on the substrate 1 by CVD, the silicon oxide film is anisotropically etched by reactive ion etching (RIE) to form sidewall spacers 13 on the side walls of each of the n type gate electrode 10N and p type gate electrode 10P. By this anisotropic etching, the silicon oxide film 9 on the n type gate electrode 10N and p type gate electrode 10P are etched away.

Then, an n conductivity type impurity (such as As or P) is implanted into the p well 5 to form heavily doped n⁺ type semiconductor regions (first semiconductor regions) 14 which will be the source and drain of the n channel MISFET. The impurity (first impurity) is also implanted into the n type gate electrode 10N and p type gate electrode 10P which will be the gate electrodes of the n channel MISFET, whereby n type silicon layers 15 are formed thereon, respectively.

A p conductivity type impurity (fourth impurity such as B) is then implanted into the n well 4 to form heavily doped p⁺ type semiconductor regions (second semiconductor regions) 16 which will be the source and drain of the p channel MISFET. At this time, the impurity is also introduced into the p type gate electrode lop which will be the gate electrode of the p channel type MISFET, whereby a p type silicon layer 17 is formed thereon.

By the above-described steps, the n channel type MISFET (third MISFET) Qn equipped with the n type gate electrode 10N and having the n⁺ type semiconductor regions 14 as source and drain and the p channel type MISFET (fourth MISFET) Qp equipped with the p type gate electrode 10P and having the p⁺ type semiconductor regions 16 as source and drain can be formed in the peripheral circuit region, while the n channel type (first channel type) MISFET QL (first MISFET) equipped with the n type gate electrode 10N and having the n⁺ type semiconductor regions 14 as source and drain and the n channel type MISFET QH (second MISFET) equipped with the p type gate electrode 10P and having the n⁺ type semiconductor regions 14 as source and drain can be formed in the memory cell region. These MISFETs QL and QH constitute the memory cells of the mask ROM of Embodiment 1 described above referring to FIGS. 1 and 2.

The MISFETs QL and QH of Embodiment 1 can be formed without addition of a new step (exclusive step for mask ROM) to the step of forming the n channel MISFET Qn and p channel MISFET Qp in the peripheral circuit region. It is therefore possible to shorten TAT for the manufacture of the semiconductor integrated circuit device having a mask ROM according to Embodiment 1. In addition, since a mask exclusively used for the formation of MISFETs QL and QH is not necessary, the production cost can be reduced.

In the MISFETs QL and QH of Embodiment 1 thus formed, the threshold voltages of the MISFETs QL and QH are determined by the work functions of the n type gate electrode 10N and p type gate electrode 10P. Compared with a method of implanting threshold-voltage regulating ions into a well below a gate electrode, fluctuations of the threshold voltage among plurality of MISFETs QL or MISFETs QH can be reduced. In short, Embodiment 1 makes it possible to manufacture a mask ROM having good controllability.

When threshold-voltage regulating ions are implanted into a well below a gate electrode, ion implantation is carried out through the gate insulating film 7, which may presumably cause inconveniences such as deterioration in the reliability of the gate insulating film 7, increase in the junction leak current of the MISFETs QL and QH and occurrence of crystal defects of the substrate 1 (p well 5). Such inconveniences can be prevented in Embodiment 1, because threshold-voltage regulating ions are implanted into the n type gate electrode 10N and p type gate electrode 10P.

In the MISFETs QL and QH of Embodiment 1 thus formed, threshold-voltage regulating ions are implanted into the n type gate electrode 10N and p type gate electrode 10P so that a mask (photoresist film) used for the formation of the n⁺ type semiconductor regions 14 and a mask (photoresist film) used for the formation of the p⁺ type semiconductor regions 16 can be used as are. This makes it possible to decrease the energy upon implantation of threshold-voltage regulating ions, thereby thinning the photoresist film used therefor. In addition, threshold-voltage regulating ions are implanted at a small energy so that the minimum processing size of a memory cell pattern can be reduced. As a result, the memory cell area of the mask ROM of Embodiment 1 can be reduced in size. The down sizing of the memory cell area leads to a reduction in the production cost of the semiconductor integrated circuit device of Embodiment 1.

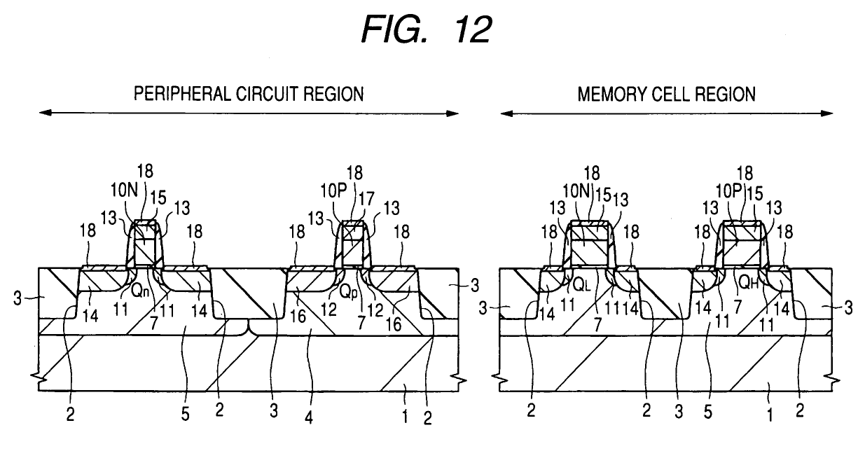

As illustrated in FIG. 12, after washing the surface of the substrate 1, a Co (cobalt) film and a Ti (titanium) film are deposited successively on the substrate 1 by sputtering. The substrate 1 is then heat treated to form a CoSi₂ layer 18 as a silicide layer on the n⁺ type semiconductor regions 14, p⁺ type semiconductor regions 16, n type gate electrode 10N and p type gate electrode 10P. The formation example of the CoSi₂ layer 18 is shown in Embodiment 1, but instead of the CoSi₂ layer 18, a refractory metal silicide layer such as NiSiₓ layer, WSiₓ layer, MoSiₓ layer, TiSiₓ layer or TaSix layer may be formed using Ni (nickel), W (tungsten), Mo (molybdenum), Ti (titanium) or Ta (tantalum).

After the unreacted Co film and Ti film are etched away, the substrate 1 is heat treated to decrease the resistance of the CoSi₂ layer 18.

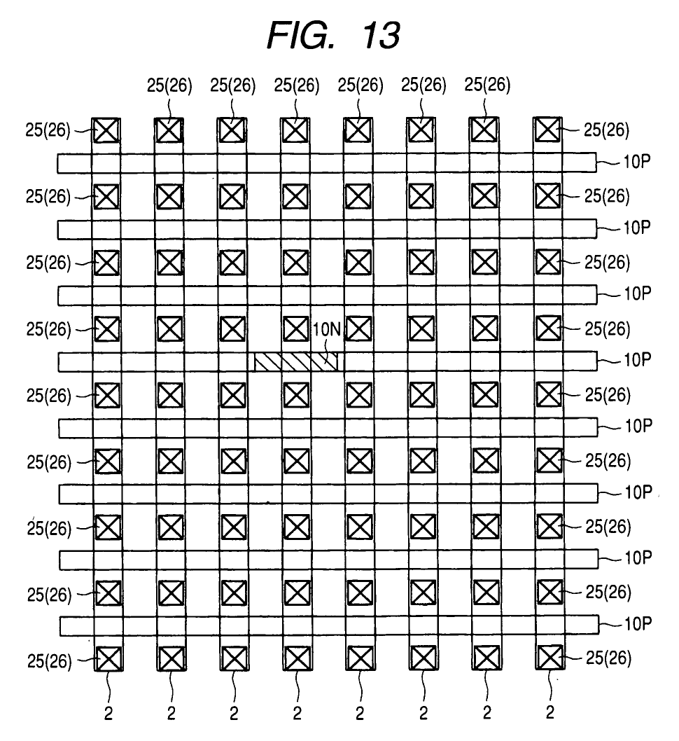

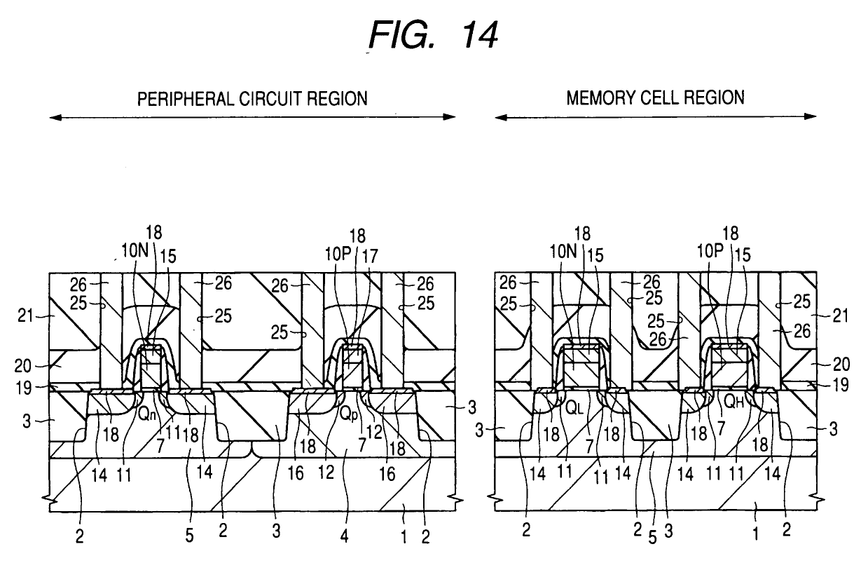

As illustrated in FIGS. 13 and 14, a silicon nitride film 19 of about 50 nm thick is deposited on the substrate 1, for example, by CVD. The silicon nitride film 19 functions as an etching stopper layer during the formation of contact holes, which will be described later.

A PSG film 20 is formed by application on the silicon nitride film 19 as an interlayer insulating film, followed by heat treatment to planarize the PSG film. A silicon oxide film 21 is deposited on the PSG film 20 by plasma CVD. Instead of the deposition of the PSG film 20, it is also possible to deposit the silicon oxide film 21 on the silicon nitride film 19 and then polish the surface of the silicon oxide film 21 by CMP to planarize its surface. A silicon nitride film (not illustrated) is deposited on the silicon oxide film 21, for example, by CVD.

By etching with a photoresist film as a mask, the silicon nitride film is patterned. After removal of the photoresist film, the silicon oxide film 21 and PSG film 20 are etched successively with the remaining silicon nitride film as a mask to form opening portions. The silicon nitride film which lies on the silicon oxide film 21 and the silicon nitride film 19 which has appeared from the bottom of the opening portions are etched away to form contact holes 25 over the n⁺ type semiconductor regions 14, p⁺ type semiconductor regions 16, n type gate electrode 10N and p type gate electrode 10P. The contact holes 25 reaching the n type gate electrode 10N and p type gate electrode 10P are formed in a region not illustrated in FIGS. 13 and 14.

A Ti film of about 10 nm thick and a TiN film of about 50 nm thick are deposited successively by sputtering as barrier films on the silicon oxide film 21 including the inside of the contact holes 25, followed by heat treatment at from 500 to 700° C. for 1 minute. A W film, for example, is deposited as a conductive film on the silicon oxide film 21 and barrier films by CVD and the contact holes 25 are filled with the W film. The W film, TiN film and Ti film on the silicon oxide film 21 are removed by etchback or CMP to leave the W film, TiN film and Ti film in the contact holes 25. In such a manner, a plug 26 having the TiN film and Ti film as barrier films and W film as a main conductive layer is formed in each of the contact holes 25.

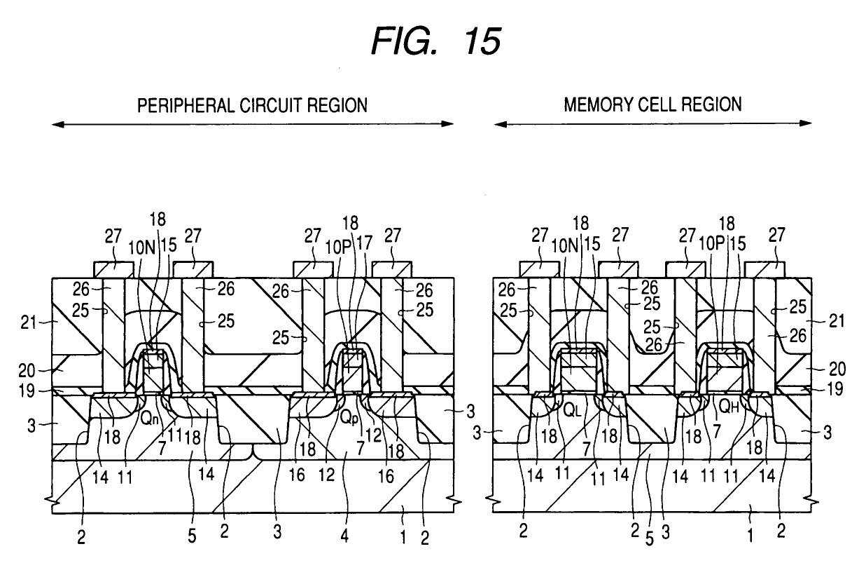

As illustrated in FIG. 15, a W film is deposited on the silicon oxide film 21 and plug 26, for example, by sputtering. By dry etching with a photoresist film as a mask, the W film is patterned, whereby interconnects 27 are formed.

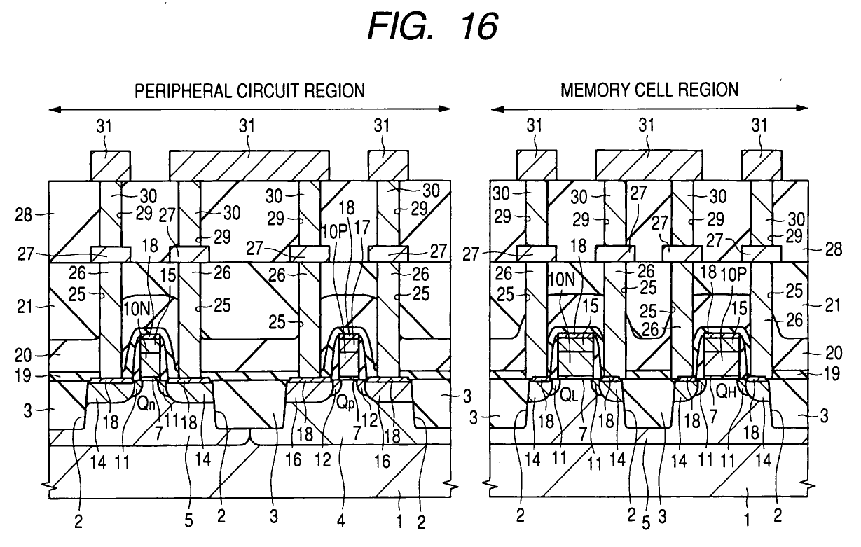

As illustrated in FIG. 16, an interlayer insulating film 28 is then formed by depositing a silicon oxide film on the substrate 1. With a photoresist film patterned by photolithography as a mask, the interlayer insulating film 28 is etched to form contact holes 29 reaching the interconnects 27.

A Ti film of about 10 nm thick and a TiN film of about 50 nm thick, for example, are deposited successively on the interlayer insulating film 28 including the inside of each of the contact holes 29, for example, by sputtering, followed by heat treatment at from about 500 to 700° C. for 1 minute. A W film, for example, is deposited as a conductive film over the barrier films and interlayer insulating film 28, for example, by CVD to fill the W film in the contact holes 29. The Ti film, TiN film and W film on the interlayer insulating film 28 are removed, while the Ti film, TiN film and W film are left in the contact holes 29 to form a plug 30 in each of the contact holes 29.

As conductive films, a Ti film, Al (aluminum) film and titanium nitride film are then deposited successively on the interlayer insulating film 28. With a photoresist film patterned by photolithography as a mask, the Ti film, Al film and titanium nitride film are etched to form interconnects 31.

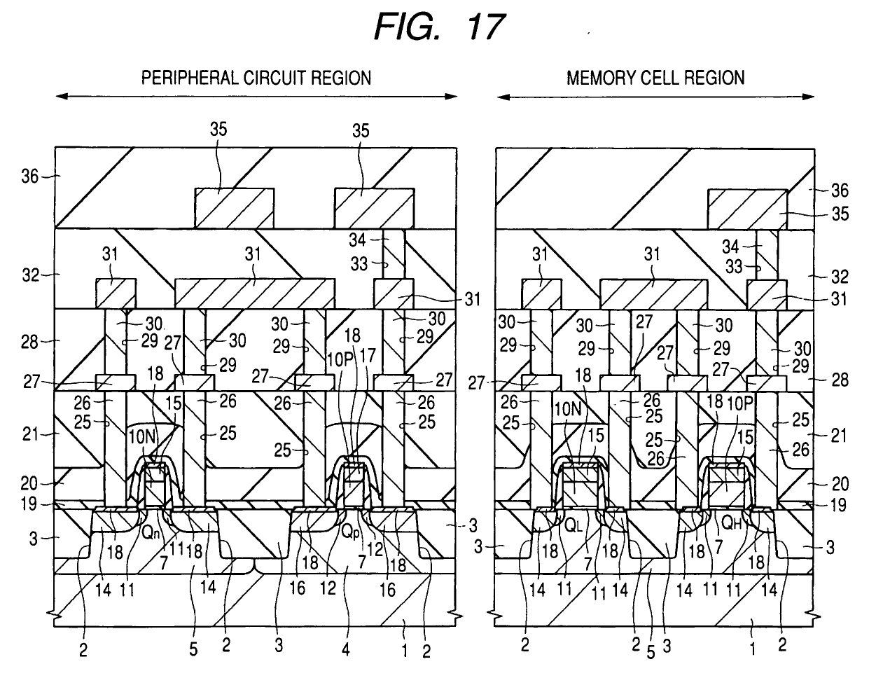

As illustrated in FIG. 17, by similar steps to those employed for the formation of the interlayer insulating film 28, contact holes 29, plugs 30 and interconnects 31, an interlayer insulating film 32, contact holes 33, plugs 34 and interconnects 35 are formed. A silicon oxide film 36 is deposited over the interconnects 35, whereby the semiconductor integrated circuit device of Embodiment 1 is manufactured. If necessary, upper-level interconnect layers may be formed thereover by repeating similar steps to those employed for the formation of the interlayer insulating film 28, contact holes 29, plugs 30 and interconnects 31.

### Embodiment 2

Embodiment 2 will next be described.

Manufacturing steps of a semiconductor integrated circuit device having a mask ROM according to Embodiment 2 are similar to those of Embodiment 1 until the deposition step of the gate insulating film 7 described referring to FIGS. 5 to 7 in Embodiment 1.

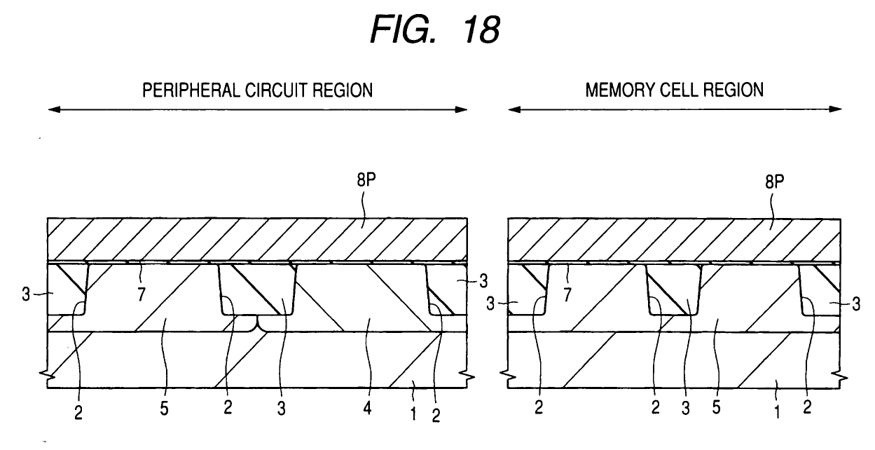

As illustrated in FIG. 18, a p type polycrystalline silicon film 8P of about 100 nm thick having a p conductivity type impurity (third impurity) doped therein is deposited as a conductive film on the substrate 1, for example, by CVD.

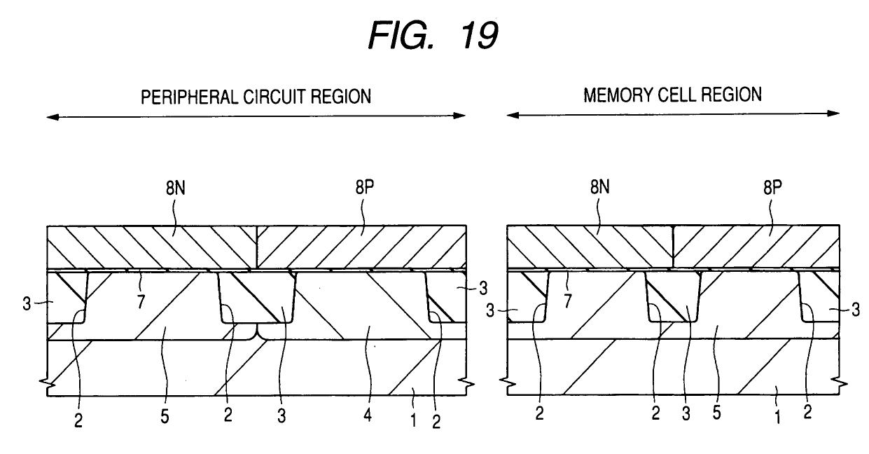

As illustrated in FIG. 19, with a photoresist film patterned by photolithography as a mask, an impurity (second impurity (such as P or As)) having an n conductivity type is implanted selectively into the p type polycrystalline silicon film 8P to form an n type polycrystalline silicon film 8N. At this time, a concentration ratio of the n conductivity type impurity to the p conductivity type impurity in the n type polycrystalline silicon film 8N is controlled so that the former one is greater than the latter one, for example, about 8:4. A region into which the n conductivity type impurity has been implanted is similar to that of Embodiment 1 (refer to FIG. 5).

Formation of the p type polycrystalline silicon film 8P and n type polycrystalline silicon film 8N in such a manner enables omission of the step (refer to FIGS. 5 to 7) of Embodiment 1 of implanting an impurity into the polycrystalline silicon film 8 for the formation of the p type polycrystalline silicon film 8P. In short, Embodiment 2 enables shortening of TAT for the manufacture of a semiconductor integrated circuit device having a mask ROM compared with Embodiment 1. In addition, Embodiment 2 enables reduction in the production cost compared with Embodiment 1 because a mask exclusively used for the formation of the p type polycrystalline silicon film 8P is not necessary.

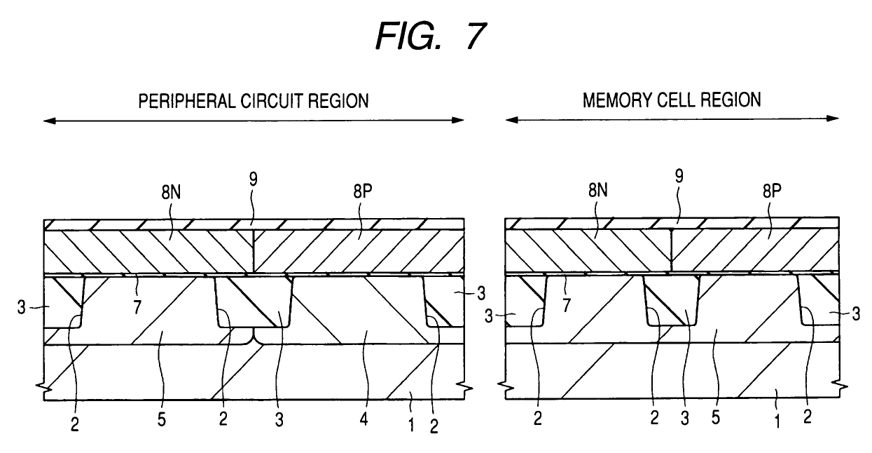

Then, by the steps (FIGS. 7 to 17) on and after the formation step of the silicon oxide film 9 as described in Embodiment 1, formation of the semiconductor integrated circuit device of Embodiment 2 is completed.

Similar advantages to those of Embodiment 1 can be available by Embodiment 2.

### Embodiment 3

Embodiment 3 will next be described.

Manufacturing steps of a semiconductor integrated circuit device having a mask ROM according to Embodiment 3 are similar to those of Embodiment 1 until the steps described referring to FIGS. 1 to 4 in Embodiment 1.

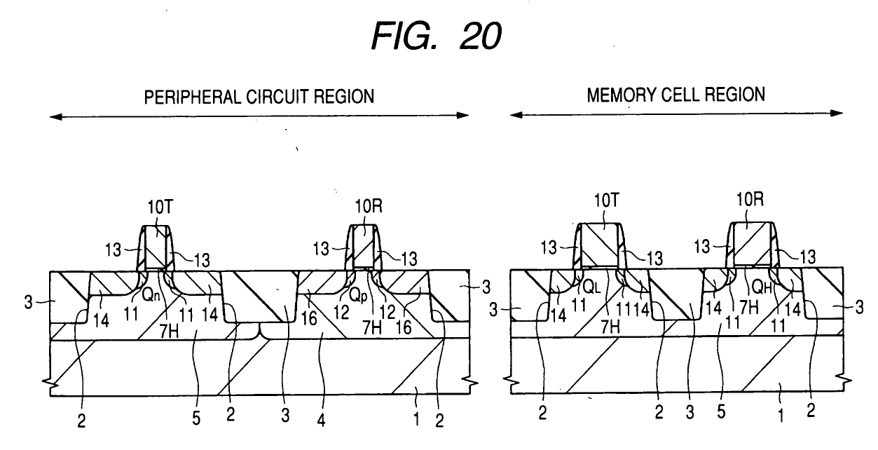

As illustrated in FIG. 20, the surface of the substrate 1 (n well 4 and p well 5) is wet cleaned with, for example, a hydrofluoric acid cleaning solution, followed by deposition of an HfO₂ film (having a specific dielectric constant of about 25), which is a high dielectric constant film, on the substrate 1 by ALD, whereby clean gate insulating films 7H are formed on the surfaces of the n well 4 and p well 5. As a high dielectric constant film which will be the gate insulating film 7H, not only the HfO₂ film but also an aluminum oxide (alumina: Al₂O₃) film (having a specific dielectric constant of about 10), HfAlOₓ film (having a specific dielectric constant of about 20), HfAlOₓ(N) film (having a specific dielectric constant of about 20) or a film stack of such high dielectric constant films formed by ALD may be used.

Next, after deposition of a TaN (tantalum nitride) film (first metal film, first metal compound film or first film stack of them) on the substrate 1, the TaN film is patterned by etching with a photoresist film patterned by photolithography as a mask to form a gate electrode 10T. Then, after deposition of Ru (ruthenium) film (second metal film, second metal compound film or second film stack of them) on the substrate 1, the Ru film is patterned by etching with a photoresist film patterned by photolithography as a mask to form a gate electrode 10R. By similar steps to those described referring to FIGS. 10 and 11 in Embodiment 1, an n channel MISFET Qn equipped with the gate electrode 10T and having the n⁺ type semiconductor regions 14 as source and drain and a p channel MISFET Qp equipped with the gate electrode 10R and having the p⁺ type semiconductor regions 16 as source and drain can be formed in the peripheral circuit region, while an n channel MISFET QL equipped with the gate electrode 10T and having the n⁺ type semiconductor regions 14 as source and drain and an n channel MISFET QH equipped with the gate electrode 10R and having the n⁺ type semiconductor regions 14 as source and drain can be formed in the memory cell region. These MISFETs QL and QH constitute the memory cells of the mask ROM described referring to FIGS. 1 and 2 in Embodiment 1.

In the MISFETs QL and QH of Embodiment 3 thus formed, the threshold voltages of the MISFETs QL and QH are determined by the work function (first work function) of the gate electrode 10T and the work function (second work function) of the gate electrode 10R. Compared with a method of implanting threshold-voltage regulating ions into a well below a gate electrode, fluctuations of the threshold voltage among a plurality of MISFETs QL or a plurality of MISFETs QH can be reduced. In short, Embodiment 3 makes it possible to manufacture a mask ROM having good controllability.

In Embodiment 3, an example of forming the gate electrode 10T of the MISFET QL having a relatively low threshold voltage and the gate electrode 10R of the MISFET QH having a relatively low threshold voltage from a TaN film and a Ru film is described, but another material can be use for the formation of these gate electrodes.

Examples of the first metal film or metal compound film constituting the gate electrode 10T of the MISFET QL include TaN film, Al film, TaSiN film and NiSi film containing P, As or Sb. Examples of the second metal film or metal compound film constituting the gate electrode 10R of the MISFET QH include WN film, NiSi film, PtSi film and NiSi film containing B, Al or Pt.

It is also possible to use a NiₓSi film as a first metal compound film and Ni_{y}Si film as a second metal compound film. In this case, x and y are numerals different from each other so that the NiₓSi film and Ni_{y}Si film are different in composition. For example, NiSi film is used as the first metal compound film, while Ni₃Si film is used as the second metal compound film.

It is also possible to use a film stack obtained by stacking the first metal film and the metal compound film one after another and to use a film stack obtained by stacking the second metal film and the metal compound one after another.

These materials can be used in combination as needed, depending on the desired work function of the gate electrode 10T and the desired work function of the gate electrode 10R. Similar advantages to those described above ones are available.

By carrying out steps as described referring to FIGS. 12 to 17 in Embodiment 1, the manufacture of the semiconductor integrated circuit device of Embodiment 3 is completed.

Similar advantages to those obtained in Embodiment 1 are available in Embodiment 3.

The present invention made by the present inventors was described specifically based on some embodiments. The present invention is not limited to these embodiments but it is needless to say that changes may be made without departing from the scope of the present invention.

The semiconductor integrated circuit device and manufacturing method thereof according to the present invention can be applied to, for example, a semiconductor integrated circuit device having a mask ROM and manufacturing steps thereof.

1. A semiconductor integrated circuit device, comprising:
a plurality of first channel type first MISFETs having a first gate electrode of a first conductivity type; and
a plurality of first channel type second MISFETs having a second gate electrode of a second conductivity type,
wherein the first MISFETs and the second MISFETs constitute a memory cell of a mask ROM.

2. A semiconductor integrated circuit device according to claim 1,
wherein data is stored in the memory cell according to a difference in work function between the first gate electrode and the second gate electrode.

3. A semiconductor integrated circuit device according to claim 2,
wherein the first MISFET has a lower threshold voltage than the second MISFET.

4. A semiconductor integrated circuit device according to claim 1,
wherein a first impurity having a first conductivity type has been implanted into the respective surfaces of the first gate electrode and the second gate electrode.

5. A semiconductor integrated circuit device according to claim 4,
wherein the first conductivity type is an n type,
wherein the second conductivity type is a p type, and
wherein the first MISFET and the second MISFET are each an n channel type MISFET.

6. A semiconductor integrated circuit device according to claim 1,
wherein a second impurity having a first conductivity type and a third impurity having a second conductivity type have been implanted into the first gate electrode, and
wherein an implantation amount of the second impurity is greater than an implantation amount of the third impurity in the first gate electrode.

7. A semiconductor integrated circuit device according to claim 6,
wherein a first impurity having a first conductivity type has been implanted further into the respective surfaces of the first gate electrode and the second gate electrode.

8. A semiconductor integrated circuit device according to claim 7,
wherein the first conductivity type is an n type,
wherein the second conductivity type is a p type, and
wherein the first MISFET and the second MISFET are each an n channel type MISFET.

9. A semiconductor integrated circuit device, comprising:
a plurality of first channel type first MISFETs having a first gate electrode equipped with a first work function and made of a first metal film, a first metal compound film or a first film stack thereof; and
a plurality of first channel type second MISFETs having a first gate electrode equipped with a second work function and made of a second metal film, a second metal compound film or a second film stack thereof,
wherein the first MISFETs and the second MISFETs constitute a memory cell of a mask ROM, and
wherein data is stored in the memory cell according to a difference in work function between the first gate electrode and the second gate electrode.

10. A semiconductor integrated circuit device according to claim 9,
wherein the first MISFET has a lower threshold voltage than the second MISFET.

11. A semiconductor integrated circuit device according to claim 9,
wherein the first metal film, first metal compound film or first film stack thereof has, as a main component, a TaN film, Al film, TaSiN film or NiSi film containing P, As or Sb, and
wherein the second metal film, second metal compound film or second film stack thereof has, as a main component, an Ru film, WN film, NiSi film, PtSi film or NiSi film containing B, Al or Pt.

12. A manufacturing method of a semiconductor integrated circuit device having a memory portion and a peripheral circuit portion in a first region and a second region of a semiconductor substrate, respectively, comprising the steps of:
(a) forming a first conductive film having a first conductivity type and a second conductive film having a second conductivity type in each of the first region and the second region;
(b) patterning the first conductive film and the second conductive film to form a first gate electrode of the first conductivity type and a second gate electrode of the second conductivity type in the first region and a third gate electrode of the first conductivity type and a fourth gate electrode of the second conductivity type in the second region;
(c) selectively implanting a first impurity of the first conductivity type into the surface of the semiconductor substrate including the surfaces of the first gate electrode, second gate electrode and third gate electrode to form first semiconductor regions of the first conductivity type, thereby forming, in the first region, a plurality of first channel type first MISFETs equipped with the first gate electrode and having the first semiconductor regions as source and drain and a plurality of first channel type second MISFETs equipped with the second gate electrode and having the first semiconductor regions as source and drain, while forming, in the second region, a plurality of first channel type third MISFETs equipped with the third gate electrode and having the first semiconductor regions as source and drain; and
(d) selectively implanting a fourth impurity of the second conductivity type into the surface of the semiconductor substrate including the surface of the fourth gate electrode to form second semiconductor regions of the second conductivity type, thereby forming, in the second region, a plurality of second channel type fourth MISFETs equipped with the fourth gate electrode and having the second semiconductor regions as source and drain.

13. A manufacturing method of a semiconductor integrated circuit device according to claim 12,
wherein in the step (a), the first conductive film and the second conductive film are formed by selectively implanting, after formation of a silicon film over the semiconductor substrate, a second impurity of the first conductivity type and a third impurity of the second conductivity type in the silicon film, respectively.

14. A manufacturing method of a semiconductor integrated circuit device according to claim 12,
wherein in the step (a), the first conductive film and the second conductive film are formed by forming a silicon film having a third impurity of the second conductivity type introduced therein over the semiconductor substrate and selectively implanting a second impurity of the first conductivity type in the silicon film, and
wherein an implantation amount of the second impurity is greater than an implantation amount of the third impurity in the first conductive film.

15. A manufacturing method of a semiconductor integrated circuit device according to claim 12,
wherein the first conductivity type is an n type,
wherein the second conductivity type is a p type,
wherein the first MISFETs, the second MISFETs and the third MISFETs are each an n channel MISFET, and
wherein the fourth MISFETs are each a p channel MISFET.

16. A manufacturing method of a semiconductor integrated circuit device according to claim 12,
wherein the first MISFETs and the second MISFETs constitute a memory cell of a mask ROM.

17. A manufacturing method of a semiconductor integrated circuit device having a memory portion and a peripheral circuit portion in a first region and a second region of a semiconductor substrate, respectively, comprising the steps of:
(a) forming a first metal film, a first metal compound film, or a first film stack thereof equipped with a first work function over the semiconductor substrate and patterning the first metal film, first metal compound film, or first film stack thereof to selectively leave the film or film stack to form a first gate electrode in the first region and a third gate electrode in the second region;
(b) forming a second metal film, a second metal compound film, or a second film stack thereof equipped with a second work function over the semiconductor substrate and patterning the second metal film, second metal compound film, or second film stack thereof to selectively leave the film or film stack to form a second gate electrode in the first region and a fourth gate electrode in the second region;
(c) selectively implanting a first impurity of the first conductivity type into the surface of the semiconductor substrate to form first semiconductor regions of the first conductivity type, thereby forming, in the first region, a plurality of first channel type first MISFETs equipped with the first gate electrode and having the first semiconductor regions as source and drain and a plurality of first channel type second MISFETs equipped with the second gate electrode and having the first semiconductor regions as source and drain, while forming, in the second region, a plurality of first channel type third MISFETs equipped with the third gate electrode and having the first semiconductor regions as source and drain; and
(d) selectively implanting a fourth impurity of the second conductivity type into the surface of the semiconductor substrate to form second semiconductor regions of the second conductivity type, thereby forming, in the second region, a plurality of second channel type fourth MISFETs equipped with the fourth gate electrode and having the second semiconductor regions as source and drain.

18. A manufacturing method of a semiconductor integrated circuit device according to claim 17,
wherein the first conductivity type is an n type,
wherein the second conductivity type is a p type,
wherein the first MISFETs, the second MISFETs and the third MISFETs are each an n channel MISFET, and
wherein the fourth MISFETs are each a p channel MISFET.

19. A manufacturing method of a semiconductor integrated circuit device according to claim 17,
wherein the first MISFETs and the second MISFETs constitute a memory cell of a mask ROM.

20. A manufacturing method of a semiconductor integrated circuit device according to claim 17,
wherein the first metal film, first metal compound film or first film stack thereof has tantalum nitride as a main component, and
wherein the second metal film, second metal compound film, or second film stack thereof has ruthenium as a main component.
